(19) United States
(12) Patent Application Publication
(10) Pub. No.: US 2023/0125412 A1
(43) Pub. Date: Apr. 27, 2023

(54) AUTONOMOUS DIMM WRITE LEVELING TRAINING

(71) Applicant: Intel Corporation, Santa Clara, CA (US)

(72) Inventors: Saravanan SETHURAMAN, Portland, OR (US); Tonia M. ROSE, Wendell, NC (US); John V. LOVELACE, Driftwood, TX (US); George VERGIS, Portland, OR (US)

(21) Appl. No.: 18/086,639

(22) Filed: Dec. 21, 2022

(51) Int. Cl. G11C 7/10; G11C 7/22

(52) U.S. Cl. CPC G11C 7/1084; G11C 7/222; G11C 7/1048

(57) ABSTRACT

An apparatus is described. The apparatus includes a data buffer chip having write leveling training circuitry. The write leveling training circuitry to detect when a sampled value of a WL pulse within a memory chip has changed. Another apparatus is described. The other apparatus includes a registering clock driver (RCD) chip having write leveling training circuitry to determine when to send a write command to a memory chip and a data buffer chip during an external write leveling training process for the memory chip.

### BACKGROUND OF THE INVENTION

As the bring-up of memory systems becomes increasingly complex and time-consuming, engineers are seeking ways to reduce the complexity and/or bring-up time from the perspective of the host system.

### BRIEF DESCRIPTION OF DRAWINGS

FIGS. 1a, 1b, 1c, 1d, 1e, 1f pertain a prior art DIMM write leveling training process;

FIG. 2 pertains to an improved write leveling training process;

FIG. 3 depicts a computer system.

### DETAILED DESCRIPTION

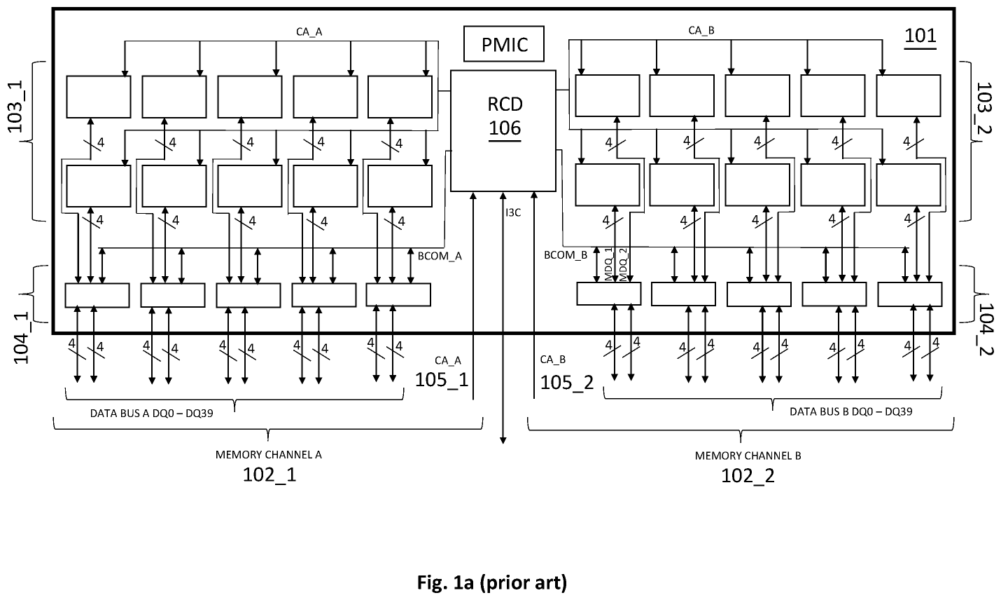

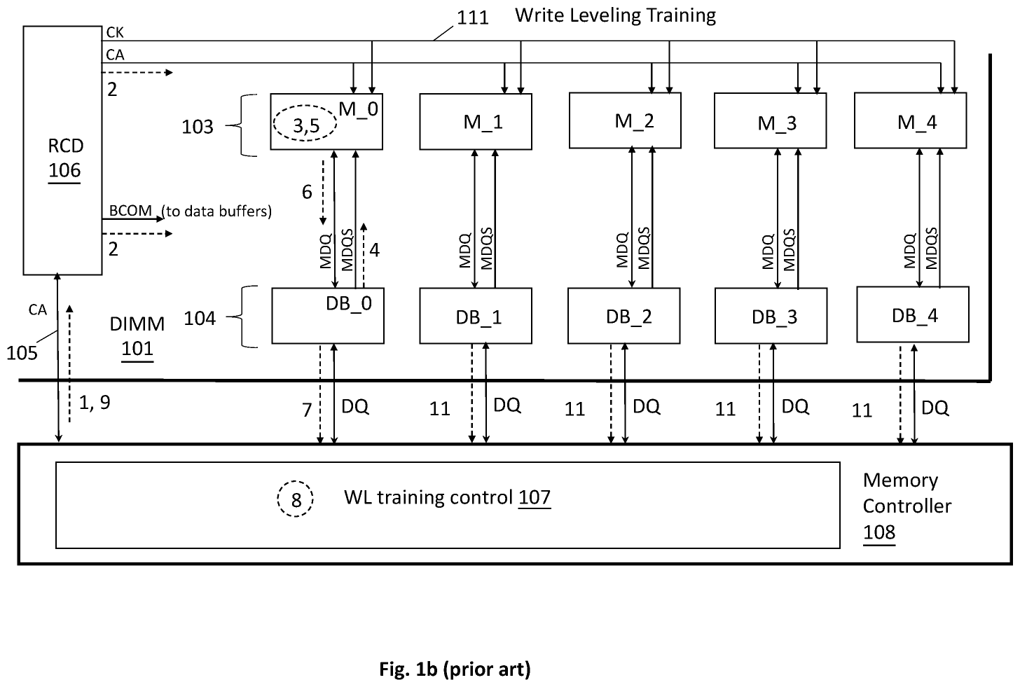

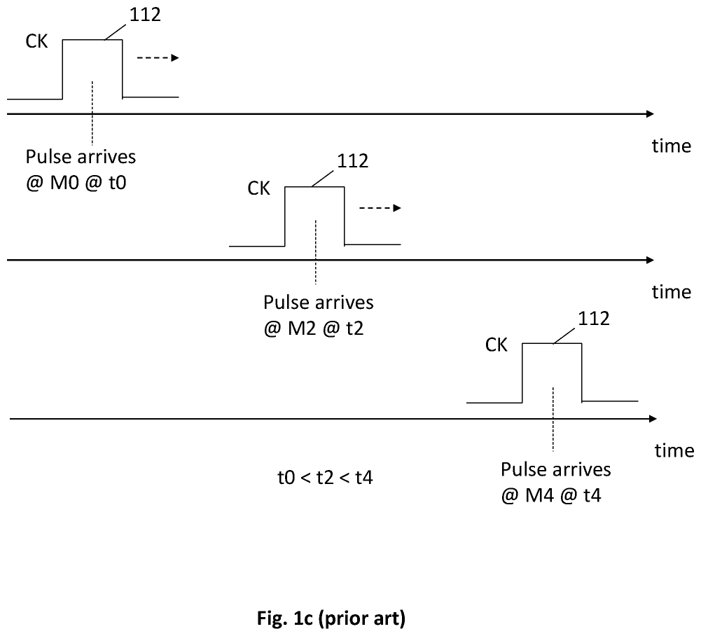

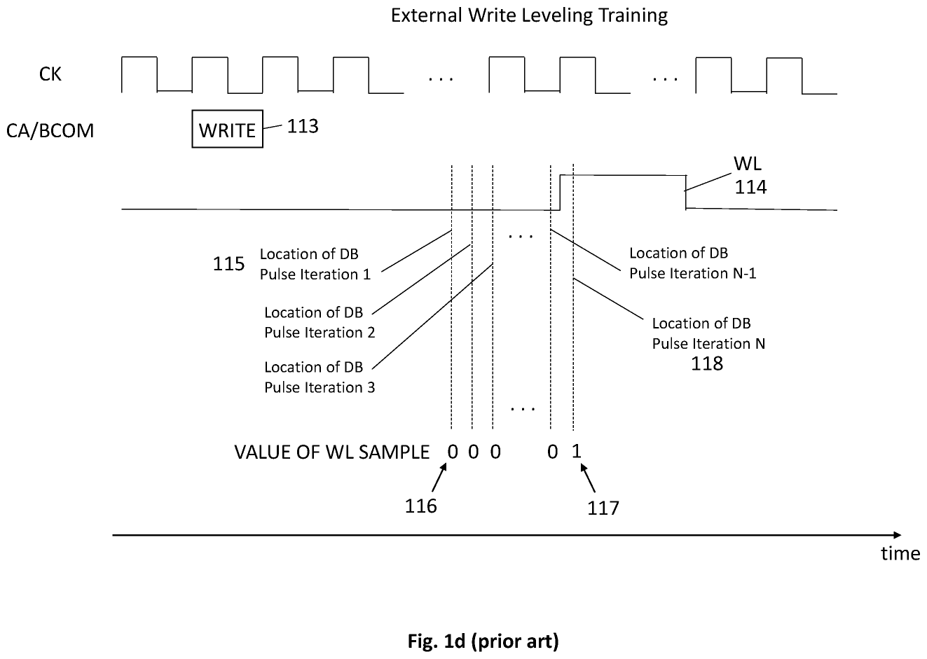

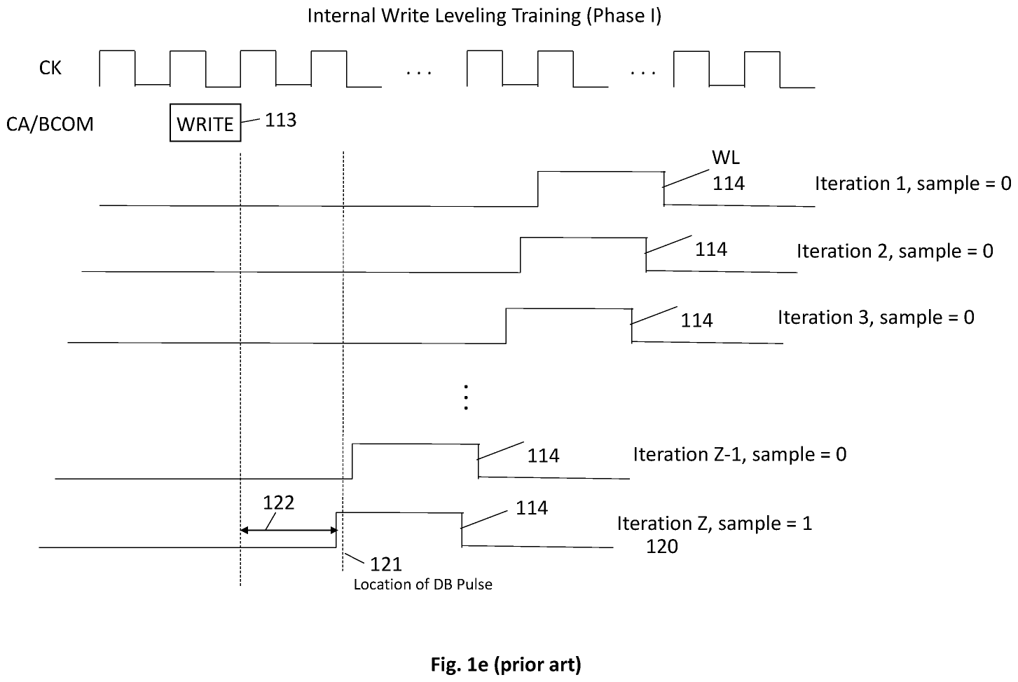

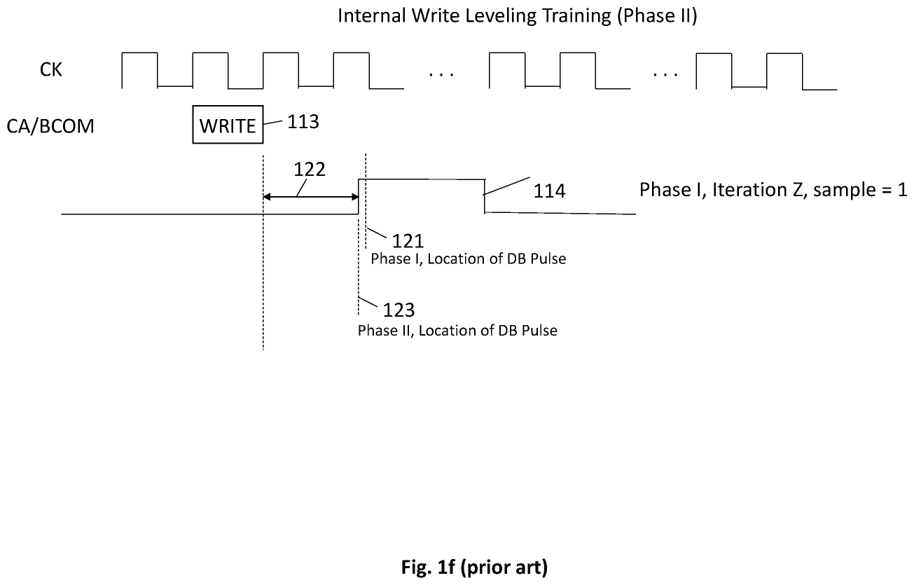

FIG. 1a shows a traditional “buffered” dual in-line memory module (DIMM) 101 that is, e.g., compliant with a Joint Electron Device Engineering Council (JEDEC) dual data rate (DDR) industry standard (e.g., DDR5). As observed in FIG. 1, a first memory channel 102_1 is coupled to the left hand (“A”) side of the DIMM 101 and a second memory channel 102_2 is coupled to the right hand (“B”) side of the DIMM 101.

A rank of memory chips 103_1 and corresponding data buffers 104_1 for the first memory channel 101_1 are disposed on the A side of the DIMM 101 while another rank of memory chips 103_2 and corresponding data buffers 104_2 for the second memory channel 101_2 are disposed on the B side of the DIMM 101.

The width of the data bus for both memory channels is 40 bits where 32 bits are for customer data and 8 bits are for error correction code (ECC) information. The 40 bit width requires ten X4 memory chips 103_1, 103_2 for each memory channel 101. The ten X4 memory chips 104_1, 104_2 are arranged per channel as a first upper group of five X4 memory chips and a second lower group of five X4 memory chips.

Each memory channel 101_1, 101_2 also includes its own respective command/address (CA) bus 105_1, 105_2. The respective CA bus 105_1, 105_2 for both memory channels 101_1, 101_2 is intercepted by the DIMM's register clock driver (RCD) chip 106 (by contrast, a memory channel's data bus wires are coupled to the corresponding data buffers 104_1, 104_2 on the DIMM 101 which are then coupled to the memory channel's rank of memory chips 103_1, 103_2).

The RCD 106 receives the command and/or address (CA) signals from the CA busses 105_1, 105_2 for both memory channels (which are generated by a host (memory controller)) and, redrives each channel's corresponding CA signals to the channel's respective memory chips 103_1, 103_2. That is, the CA signals 105_1 received for the A memory channel 101_1 are re-driven to the memory chips 103_1 and on the A side of the DIMM 101, whereas, the CA signals 105_2 received for the B memory channel 101_2 are re-driven to the memory chips 103_2 on the B side of the DIMM 101.

According to various JEDEC standards, a buffer communication (BCOM) bus exists between the RCD 106 and the data buffers 104_1, 104_2 for a particular memory channel. That is, there is one BCOM bus (“BCOM_A”) that couples the RCD 106 to the data buffers 104_1 of the A memory channel and another BCOM bus (“BCOM_B”) that couples the RCD 106 to the data buffers 104_2 of the B memory channel.

During bring-up of the DIMM 100, the data paths between the data buffers 104 and the memory chips 103 are trained. Here, during nominal operation, write data emitted by a particular data buffer is sent over an MDQ data channel to the memory chip(s) that is/are coupled to the data buffer by way of the MDQ data channel. A common implementation, as observed in FIG. 1a, is to couple two different memory chips with two different, respective MDQ data channels to a same data buffer.

The data buffer 104 also sends an MDQS strobe signal along with the write data for a particular MDQ data channel. A receiving memory chip is designed to latch the write data from the MDQ channel on a particular (e.g., rising) edge of the MDQS strobe signal (in DDRS, the MDQS strobe signal is a differential signal defined as the difference between two physical signals MDQS_t and MDQS_c that are sent from the data buffer to the memory chip).

Referring to FIG. 1b, notably, the path lengths from the data buffers 104 to the memory chips 103 of a same rank are comparable (for ease of drawing and explanation FIG. 1b depicts a more simplistic memory channel in which each data buffer only drives one memory chip and there are only five data buffers and memory chips per channel). By contrast, the path lengths of the clock signal (CK) wiring 111 that runs from the RCD 106 to the memory chips 103 of a same rank varies greatly as a function of the distance from the RCD 106 to a particular memory chip within the rank (specifically, the clock signal wire distance is much greater for the memory chips that are farther away from the RCD 106 than for the memory chips that are closer to the RCD 106).

Because of the clock signal wire length differences, the memory chips 103 will observe different CK clock signal timings. Specifically, referring to FIG. 1c, the rising edge of a particular CK clock pulse 112 that is sent by the RCD will be observed much later in time (t4) by the memory chip M4 that is farthest from the RCD 106 than the memory chip MO that is closest to the RCD 106 (t0). Corresponding differences in the CK pulse's arrival time will be observed by the memory chips M1, M2, M3 that are between the memory chips M0, M4 that are farthest from and closest to the RCD chip 106.

The arrival time of a CK pulse at a memory chip is pertinent because a memory chip expects to receive write data based on its CK clock signal. Specifically, for example, a memory chip expects to receive write data within a time window whose temporal position is defined, e.g., as some number of CK clock cycles after the memory chip has received a write command.

Here, with the MDQ data and MDQS strobe signals of a write operation all arriving at the memory chips of a same rank at approximately the same time (because the lengths of the MDQ/MQDS wires between the data buffers 104 and the memory chips 103 are approximately the same), while, the respective pulses of the CK clock signal are received by the memory chips 103 at different times, a skewing problem is designed into the DIMM 101.

In order to address the skewing problem, the data buffers 104 are designed to impose delay into the MDQ/MDQS write signals that are driven to the memory chips 103 to compensate for the memory chips' different CK pulse arrival times. Thus, as an example, the data buffer DB_4 that sends write data to the memory chip M4 that is farthest away from the RCD 106 will impose more delay into its respective MDQ/MDQS signals than a data buffer, e.g., DB_1, that sends write data to a memory chip M1 that is closer to the RCD 106.

As part of the DIMM's bring-up, the memory controller 108 of the host system that is coupled to the DIMM 101 will perform a “write leveling” training process that determines an appropriate delay to impose at each data buffer DB_0 through DB_4 for the rank of memory chips M_0 through M_4.

According to the write training process, as observed in FIGS. 1b and 1d, after the data buffers and memory chips of a particular rank and memory channel are placed in a wear leveling training mode, wear leveling training control circuitry 107 within the memory controller 108 of the host causes a write command 1 to be sent from the host to the RCD chip 106. The RCD chip 106 forwards 2 the write command 113 to the memory chips 103 via the CA bus and to the data buffers 104 via the BCOM bus.

In response to the write command 113, each memory chip triggers 3 an internal wear leveling (WL) pulse 114 some predetermined number of CK clock cycles after the memory chip receives the write command 113 (for ease of drawing and explanation, only data buffer DB_0 and memory chip M_0 are labeled in relation to the training process sequence). The rising edge of the WL pulse 114 within each memory chip therefore correlates to each memory chip's CK clock signal skew. As described in more detail below, the rising edge of the WL pulse 114 within a particular memory chip is a temporal reference point that the write leveling training process discovers and then utilizes to determine the buffer delay that is applied to MDQ/MDQS signals that are sent to the particular memory chip.

Concurrently, in response to the same write command 113 that causes the memory chips to generate 3 an internal WL pulse 114, the data buffers 104 send 4 a preamble signal followed by a DB pulse on the MDQS strobe wires of the MDQ/MDQS channels that couple the data buffers 104 to the memory chips 103.

For each data buffer, the sending 4 of the preamble and DB pulse is such that the DB pulse is located at some pre-programmed number of BCOM clock cycles after the data buffer's reception of the write command 113. The programming for the DB pulse's initial placement is performed by the write leveling training circuitry 107 of the host system's memory controller 108 as part of the initialization of the write leveling training process. Different buffers can be programmed with different initial DB pulse locations (e.g., the data buffers whose memory chips are farther away from the RCD 106 are programmed to place the DB pulse more BCOM clock cycles after the write command 113 than the data buffers whose memory chips are closer to the RCD).

Each memory chip samples 5 the logical value (1 or 0) of its internally generated WL pulse 114 on the rising edge of the DB pulse that it receives from its corresponding data buffer. Generally, within each memory chip, the initial location 115 of the DB pulse precedes the rising edge of the WL pulse 114 such that the initially sampled value 116 for the WL pulse is 0.

Each memory chip then reports 6 its respective sampling result to its respective data buffer along its respective MDQ data wires. The data buffers then forward 7 the received sampling results along the memory channel to the write leveling training circuitry 107 within the memory controller 108 of the host system. The write leveling training circuitry 107 analyzes 8 the results and programs 9 new DB pulse location values into the data buffers 104. Here, for instance, the new values are later in time which causes the DB pulses to encroach closer to the rising edge of the memory chip WL signals that they are used to sample.

The process then repeats with the write training circuitry causing a next write command to be sent 1, the memory chips 103 generating internal WL pulses 3, the data buffers 104 sending 4 their respective preamble and DB pulse at the newly programmed position to their respective memory chips along the MDQS strobe wires, the memory chips using their newly positioned DB pulse to sample 5 their internal WL pulse (which remains at 0 assuming the DB pulses have not yet reached the rising edges of their WL pulses) and reporting 6 the sampling results to the data buffers, which in turn, forward 7 the results to the write leveling training circuitry.

The process is then repeated for multiple iterations 116, e.g., with each new DB pulse location of each iteration placing the DB pulse closer to, and then eventually beyond, the rising edge of the WL pulse 114 within the memory chips (DB pulse location 118, iteration N in FIG. 1d), at which point, the sampled value of the WL pulse changes 117 from a 0 to a 1.

Whenever a memory chip reports a WL sample value change 117 from 0 to 1, the write leveling training circuitry 107 knows the location of the rising edge of the WL pulse 114 within the memory chip from the programmed location 118 of the DB pulse (iteration N) that caused the sample change. From this understanding, the write leveling training circuitry 107 is able to determine the memory chip's particular CK clock signal skew and an appropriate delay for the MDQ write data and MDQS strobe signals that should be programmed into the data buffer that sends these signals to the memory chip. The write leveling training circuitry 107 then causes this delay to be programmed into the data buffer.

After such respective delays have been programmed into the respective data buffers for all of the memory chips in the rank, the “external” write leveling training is complete.

The “external” write leveling training process as described above compensates for the CK skew that results from a CK pulse's finite “time of flight” from the RCD to the external pin of a memory chip where the CK signal is received. The memory chips can also have internal signal propagation delay differences amongst themselves (internal skews) owing, e.g., to manufacturing tolerances/differences of the memory chips. Specifically, the precise location of the rising edge of the WL pulse 114 relative to the write command 113 can vary from memory chip to memory chip.

As such, after the “external” write leveling process is performed, an “internal” write leveling process is performed to compensate for these skews. Here, the rising edge of a memory chip's WL pulse 114 establishes when the memory chip expects the first data transfer of a write burst after a write command is received. The internal write leveling training process moves the rising edge of the WL pulse 114 closer in time to the write command so that the memory chip's internal skews are mitigated (internal skews propagate/compound over fewer CK cycles after the write command).

Internal write leveling training is performed over two phases (Phase I and Phase II) as depicted in FIGS. 1e and 1f, respectively. Referring to FIGS. 1d and 1e, Phase I of internal write leveling training commences with the host re-programming the data buffers to move the location of their DB pulse “backward” in time from its location 118 as of the completion of the external write leveling training to a new location 121 that is closer to the write command 113. The position of the DB pulse remains fixed at the new location 121 over the course of multiple iterations of Phase I of the internal write leveling training process.

Here, as observed in FIG. 1e, with each iteration of Phase I of the internal write leveling training process, the WL pulse 114 is moved closer to the write command 113. At each iteration, the memory chips sample the new location of the WL pulse is sampled at the fixed location 121 of the DB pulse. Here, the process 1-9 as described above with respect to FIG. 1b for external write leveling training is repeated for each iteration except that at the completion of each iteration, the write leveling training circuitry 108 programs 9 a new WL pulse position into each of the memory chips (rather than programming a new DB pulse position into each of the data buffers). Eventually, as observed at iteration Z 120 of FIG. 1e, the new WL pulse position places the leading edge of the WL pulse 114 before the fixed location 121 of the DB pulse and the sampled value of the WL pulse 114 changes from a 0 to a 1. Phase I is completed after a sample change is observed for each of the memory chips.

Referring to FIG. 1f, Phase II performs a final tweak of the placement of the DB pulse so that it moves from its fixed location 121 of Phase I to a new location 123 that is more precisely aligned with the position of the leading edge of the WL pulse 114 at the conclusion of Phase I. Here, the external write leveling training process is essentially performed (with the WL pulse 114 located at its position at the conclusion of Phase I) but with finer time increments of the DB pulse position per iteration. When the sampled value of a memory chip's WL pulse 114 changes from 0 to 1, the new/updated position 123 of the DB pulse is programmed into the data buffer for the MDQ/MDQS channel that writes to the memory chip. Phase II is completed when the DB pulse location is updated for all of the MDQ/MDQS channels.

A problem is that the involvement of the host 107, 108 complicates the training process.

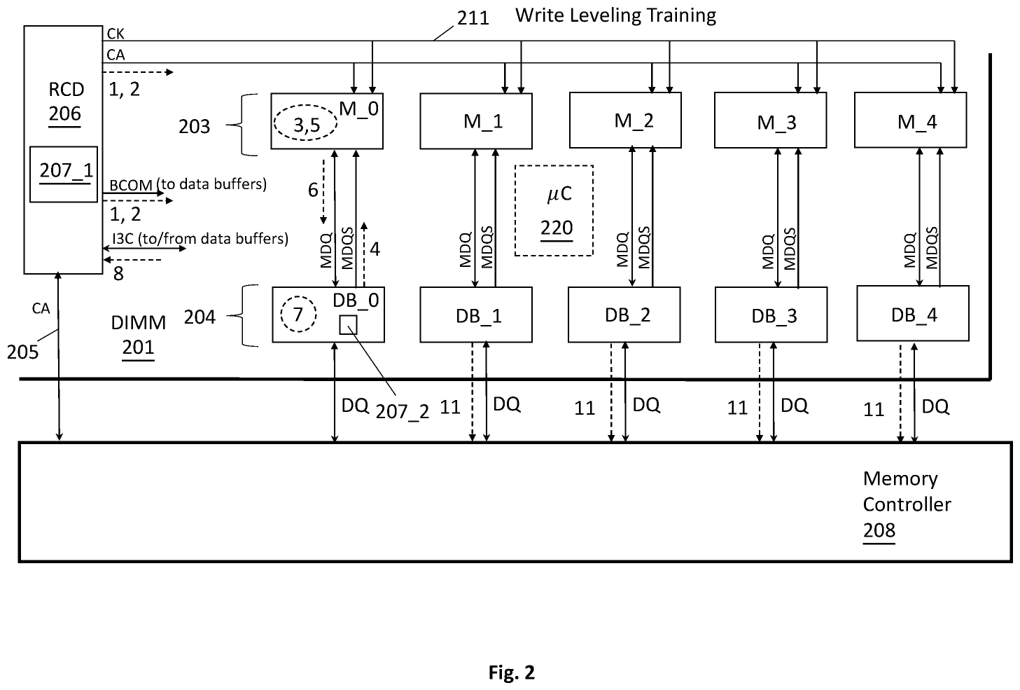

An improvement, referring to FIG. 2, is to integrate the MWD training control circuitry 207 into the data buffers 204 and the RCD 206. Here, as observed in FIG. 2, the RCD 206 includes write leveling training control circuitry 207_1 and the data buffers include write leveling training control circuitry 207_2 (for ease of drawing data buffer write leveling training circuitry 207_2 is only shown in data buffer DB_0 in FIG. 2).

For external write leveling training, the data buffer write leveling training control circuitry 207_2 does not forward the per iteration WL pulse sample to the host memory controller 208. Rather, the circuitry 207_2 analyzes the sampling result and determines 7 a new DB pulse position for its own MDQS strobe signal for the next iteration. The circuitry 207_2 can write the new DB pulse location information into the same register space of the data buffer that the host writes to in the prior art approach, or, circuitry 207_2 can set the new DB pulse location with another register and/or control circuit.

When the data buffer is ready to execute a next iteration, the data buffer sends a message 8 to the RCD 206 through, e.g., an I3C bus or the BCOM bus. When the RCD 206 receives messages 8 from all of the data buffers the RCD 206 issues a write command 2 to essentially commence the next iteration.

For Phase I of the internal write leveling training, the data buffer write leveling training control circuitry 207_2 determines the new location 121 of the DB pulse and configures the corresponding MDQ/MDQS channel to place the DB pulse at the new location 121 (e.g., by writing to the same register space of the data buffer that the host writes to in the prior art approach, or, circuitry 207_2 can set the new DB pulse location with another register and/or control circuit). The RCD 206 programs a new WL pulse location that is closer to the write command for each iteration and sends the write command 2 to commence each iteration.

The data buffer's write leveling training circuitry 207_2 receives the WL pulse sample result for each iteration and determines 7 if the sample result has changed from a 0 to a 1 (the sample result is not sent to the host memory controller 208). The write leveling training circuitry 207_2 within the data buffer sends a message 8 to the RCD 206 that notifies the RCD 206 whether the sample value has changed from a 0 to a 1. Phase I of the internal write leveling training process is completed after the RCD 206 is notified that the sample value has changed from a 0 to a 1 for each of the memory chips.

For Phase II of the internal write leveling training, the RCD's write leveling training circuitry 207_1 and the data buffer's write leveling training circuitry 207_2 act as described above for external write leveling training but where the data buffer's write leveling training circuitry 207_2 uses finer time increments for the DB pulse location per iteration.

In various embodiments the RCD 206 (and not the host) determines that write leveling training is to begin and places both the DRAM chips 203 and the data buffers 204 into a write leveling training mode by writing 1 to specific mode register (MR) space of both sets of chips 203, 204.

In various embodiments the RCD 206 and data buffers 204 are implemented with dedicated hardwired circuitry, programmable circuitry (e.g., field programmable gate array (FPGA)), circuitry that executes some form of program code such as the SSD's firmware (e.g., controller, processor) or any combination of these.

In various embodiments, rather than implement the write training control entirely in the RCD 206 and data buffers 204, write training control is implemented entirely or partially in a micro-controller 220 that is on the DIMM but not within the RCD 206 (e.g., as a stand alone micro-controller or an embedded micro-controller in some other chip on the DIMM such as the serial presence detect (SPD) chip). In this case, as just one example, the micro-controller receives testing results 8 from the data buffers and determines appropriate data buffer configurations and control flow across iterations. Notably, as part of the control flow, the micro-controller 220 can send the RCD 206 respective commands to issue the write commands 2 when appropriate. In other embodiments, the micro-controller 220 and one or more other chips on the DIMM (e.g., RCD, data buffers, SPD) share in the functions/roles of the write training control and therefore together form the write training circuitry.

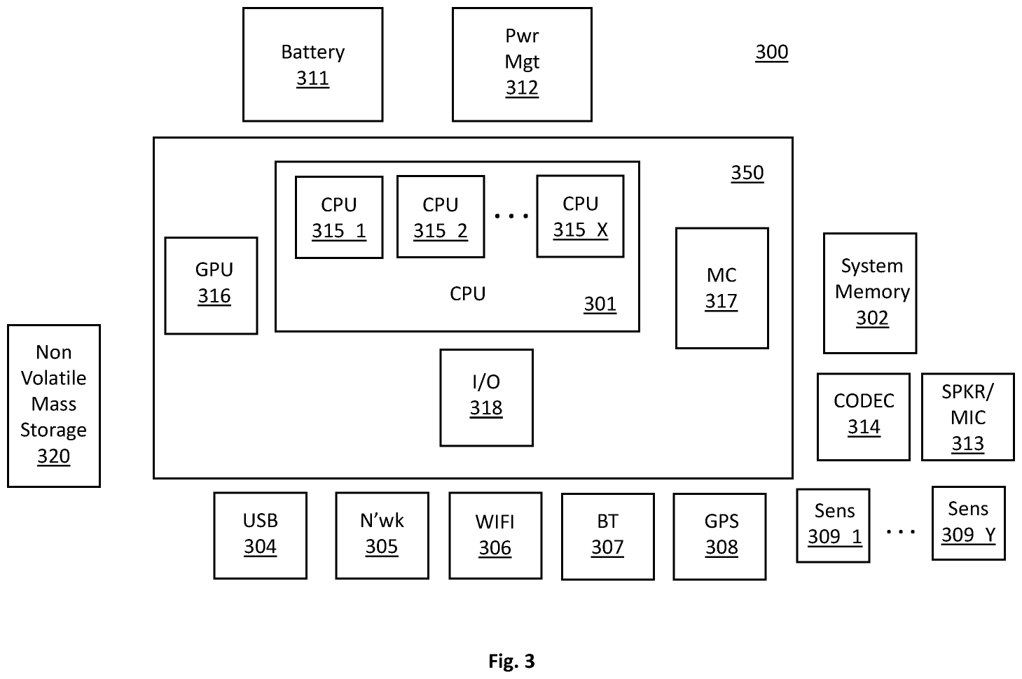

FIG. 3 depicts a basic computing system. The basic computing system 300 can include a central processing unit (CPU) 301 (which may include, e.g., a plurality of general purpose processing cores 315_1 through 315_X) and a main memory controller 317 disposed on a multi-core processor or applications processor, main memory 302 (also referred to as “system memory”), a display 303 (e.g., touchscreen, flat-panel), a local wired point-to-point link (e.g., universal serial bus (USB)) interface 304, a peripheral control hub (PCH) 318; various network I/O functions 305 (such as an Ethernet interface and/or cellular modem subsystem), a wireless local area network (e.g., WiFi) interface 306, a wireless point-to-point link (e.g., Bluetooth) interface 307 and a Global Positioning System interface 308, various sensors 309_1 through 309_Y, one or more cameras 310, a battery 311, a power management control unit 312, a speaker and microphone 313 and an audio coder/decoder 314.

An applications processor or multi-core processor 350 may include one or more general purpose processing cores 315 within its CPU 301, one or more graphical processing units 316, a main memory controller 317 and a peripheral control hub (PCH) 318 (also referred to as I/O controller and the like). The general purpose processing cores 315 typically execute the operating system and application software of the computing system. The graphics processing unit 316 typically executes graphics intensive functions to, e.g., generate graphics information that is presented on the display 303. The main memory controller 317 interfaces with the main memory 302 to write/read data to/from main memory 302. The main memory 302 can include one or more DIMMs having an RCD that controls data buffer to memory chip write training as discussed at length above. The power management control unit 312 generally controls the power consumption of the system 300. The peripheral control hub 318 manages communications between the computer's processors and memory and the I/O (peripheral) devices.

Other high performance functions such as computational accelerators, machine learning cores, inference engine cores, image processing cores, infrastructure processing unit (IPU) core, etc. can also be integrated into the computing system.

Each of the touchscreen display 303, the communication interfaces 304-307, the GPS interface 308, the sensors 309, the camera(s) 310, and the speaker/microphone codec 313, 314 all can be viewed as various forms of I/O (input and/or output) relative to the overall computing system including, where appropriate, an integrated peripheral device as well (e.g., the one or more cameras 310). Depending on implementation, various ones of these I/O components may be integrated on the applications processor/multi-core processor 350 or may be located off the die or outside the package of the applications processor/multi-core processor 350. The computing system also includes non-volatile mass storage 320 which may be the mass storage component of the system which may be composed of one or more non-volatile mass storage devices (e.g., hard disk drive, solid state drive, etc.). The non-volatile mass storage 320 may be implemented with any of solid state drives (SSDs), hard disk drive (HDDs), etc.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a data buffer chip comprising write leveling training circuitry, the write leveling training circuitry to detect when a sampled value of a WL pulse within a memory chip has changed.

2. The apparatus of claim 1 wherein the write leveling training circuitry is to, before the change of the value, determine a position of a DB pulse that is to be sent to the memory chip along an MDQS strobe wire that couples the data buffer and the memory chip.

3. The apparatus of claim 1 wherein the write leveling training circuity is to inform a register clock driver (RCD) chip of the value change.

4. The apparatus of claim 3 wherein the RCD chip is to be informed of the value change through an I3C bus that couples the data buffer chip to the RCD chip.

5. The apparatus of claim 1 wherein the detection is part of a Phase II internal write leveling training process of the memory chip.

6. The apparatus of claim 1 wherein the write leveling training circuitry is to determine a fixed DB pulse position of an MDQS strobe signal that is sent to the memory chip for a Phase I internal write leveling training process of the memory chip.

7. An apparatus, comprising:
a registering clock driver (RCD) chip comprising write leveling training circuitry to determine when to send a write command to a memory chip and a data buffer chip during an external write leveling training process for the memory chip.

8. The apparatus of claim 7 wherein the RCD chip is to receive from the data buffer results of samples of a WL pulse within the memory chip that was generated in response to the write command.

9. The apparatus of claim 7 wherein the write leveling training circuitry is to determine the external write leveling training process is complete in part because of a value change in the samples.

10. The apparatus of claim 7 wherein the write leveling training circuitry is to determine when to send a write command to a memory chip and a data buffer chip during an internal write leveling training process for the memory chip.

11. A computing system, comprising:
a plurality of processors;
a memory controller coupled to the plurality of processors;
a memory system coupled to the memory controller, the memory system comprising a DIMM, the DIMM comprising a) and b) below:
a) a data buffer chip comprising first write leveling training circuitry, the write leveling training circuitry to detect when a sampled value of a WL pulse within a memory chip has changed as part of a write leveling training process of the memory chip;
b) a registering clock driver (RCD) chip comprising second write leveling training circuitry to determine when to send a write command to the memory chip and the data buffer chip during the write leveling training process for the memory chip.

12. The computing system of claim 11 wherein the first write leveling training circuitry is to, before the change of the value, determine a position of a DB pulse that is to be sent to the memory chip along an MDQS strobe wire that couples the data buffer and the memory chip when the write leveling training process is an external write leveling training process.

13. The computing system of claim 11 wherein the first write leveling training circuity is to inform a register clock driver (RCD) chip of the value change.

14. The computing system of claim 13 wherein the RCD chip is to be informed of the value change through an I3C bus that couples the data buffer chip to the RCD chip.

15. The computing system of claim 11 wherein the detection is part of a Phase II internal write leveling training process of the memory chip.

16. The computing system of claim 1 first wherein the first write leveling training circuitry is to determine a fixed DB pulse position of an MDQS strobe signal that is sent to the memory chip for a Phase I internal write leveling training process of the memory chip.

17. The computing system of claim 11 wherein the RCD chip is to receive from the data buffer results of samples of a WL pulse within the memory chip that was generated in response to the write command.

18. The computing system of claim 11 wherein the second write leveling training circuitry is to determine an external write leveling training process is complete in part because of a value change in the samples.

19. The apparatus of claim 11 wherein the second write leveling training circuitry is to determine when to send the write command during an internal write leveling training process for the memory chip.

20. The apparatus of claim 11 wherein the second write leveling training circuitry is to determine when to send the write command during first and second phases of an internal write leveling training process for the memory chip.
